(19) United States
(12) Patent Application Publication
(10) Pub. No.: US 2026/0114274 A1
(43) Pub. Date: Apr. 23, 2026

(54) Diamond-Based Film for a Die Stack, Method for Forming a Diamond-Based Film for a Die Stack, and Die Stack

(71) Applicant: Intel Corporation, Santa Clara, CA (US)

(72) Inventors: Casey THIELEN, Chandler, AZ (US); Rajiv MONGIA, Portland, OR (US); Je-Young CHANG, Tempe, AZ (US)

(21) Appl. No.: 19/424,523

(22) Filed: Dec. 18, 2025

Related U.S. Application Data
(60) Provisional application No. 63/913,187, filed on Nov. 7, 2025.

(51) Int. Cl. H10W 40/25; H10W 40/00; H10W 90/20

(52) U.S. Cl. CPC H10W 40/254; H10W 40/03; H10W 90/288

(57) ABSTRACT

Various examples relate to a diamond-based film for a die stack, to a method for forming a diamond-based film for a die stack, and to a die stack comprising at least one diamond-based film. The diamond-based film comprises a plurality of laser-induced graphitic structures configured to provide electrical connectivity between a first semiconductor die and a second semiconductor die arranged adjacent to the diamond-based film in the die stack.

### BACKGROUND

The realm of 3D die-stacking for microelectronics continues to mature across the industry because it allows for more efficient computing as well as a higher density of computing. This trend brings with it a primary challenge of cooling the 3D die-stack effectively. This is one of the key limitations for how many dies can be stacked.

One option to help mitigate the thermal issues of the 3D stacking trend is to use very-high thermal conductivity thin films, such as diamond, between the stacked dies, which can be silicon-based, GaN, etc. Diamond is among the most thermally conductive materials, with a conductivity ranging from 1,200 to 2,100 W/m·K. This exceptional property is attributed to its strong carbon-carbon bonding and low atomic mass, which facilitate high phonon frequencies and acoustic velocities. Additionally, diamond is an excellent electrical insulator, owing to its wide bandgap exceeding 5 eV.

### BRIEF DESCRIPTION OF THE FIGURES

Some examples of apparatuses and/or methods will be described in the following by way of example only, and with reference to the accompanying figures, in which:

FIG. 1 shows a design of a diamond spreader integrated within a 3D stacked die structure;

FIG. 2 shows an example of a diamond film with laser-created electrically conductive graphitic vias being bonded to a die via a dielectric film;

FIG. 3 shows an example of an active circuitry 3D-stacked silicon compute structure;

FIG. 4 shows a flowchart of an example of a method for forming a diamond-based film for a die stack.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures, same or similar reference numerals refer to same or similar elements and/or features, which may be identical or implemented in a modified form while providing the same or a similar function. The thickness of lines, layers, and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

Various examples of the present disclosure relate to a 3D die stackup with diamond interposer and carbon-based, electrically conductive integrated structure.

For 3D stacked dies to communicate directly with each other, they may have electrical contacts that penetrate through the films in between those dies. Those contacts are generally created using copper or solder. The electrical connections are enabled through either a solder reflow process that connects the signals, power, and ground connections between those dies. More recently, hybrid bond interconnect (HBI) is becoming a popular method of directly bonding the copper pads directly (without solder) as well as the dielectric layers.

For direct-bonding of the layers in the 3D die-stack, an added layer, such as diamond, may have to be compatible with this process, and because thermal resistance is one of the largest limiters of the 3D stacking trend, HBI is preferred to enable direct-bonding of the layers without any gaps, which are caused by solder-bump-bonded dies.

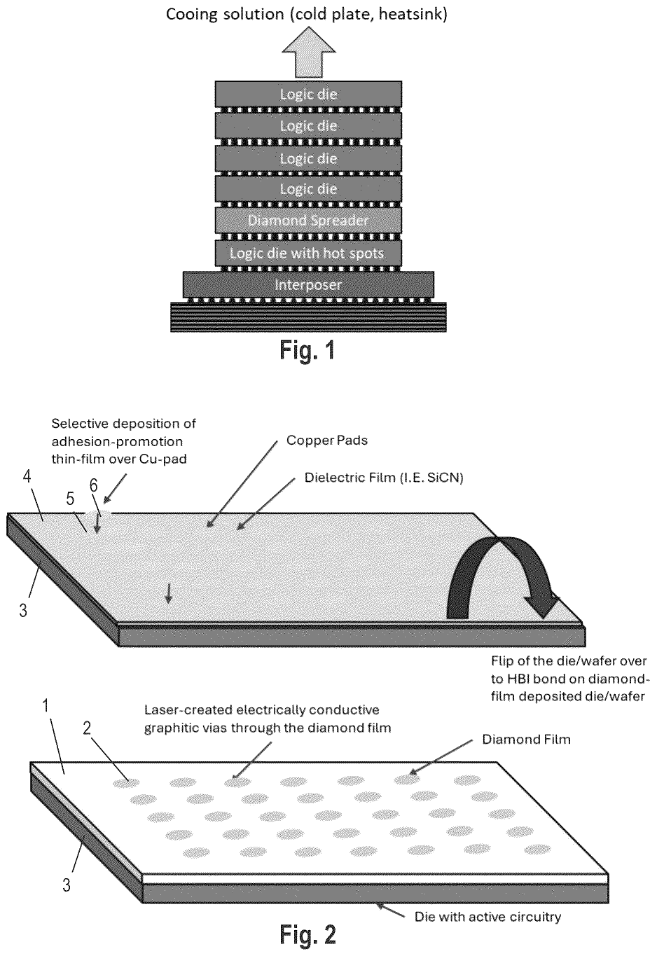

FIG. 1 illustrates a conceptual design of a diamond spreader integrated within a 3D stacked-die structure. If a diamond layer is added to a die stack, conventionally the diamond layer would have to be patterned and etched to allow an electrically conductive material, such as copper or aluminum, to fill those openings. Additional layers may be required for adhesion as well as to avoid migration of the metal fill material that would lead to shorting or increased contact resistance. All of these steps add cost and complexity to this process, and the risks multiply when attempting to increase the number of dies stacked together. To date, there might not be a known product or development initiative that has successfully implemented a diamond-layer in a 3D die stack, while enabling vertical electrical connections. However, this is theoretically feasible, assuming the ability to pattern and etch a diamond film. Additionally, diamond films, with their highly desired thermal conductivity properties, have seen significant development efforts in both silicon and GaN active die circuitry applications, making them especially useful (in theory) for managing heat in vertically stacked chips (or stacks oriented sideways). Since nearly all of 3D die stacking uses either solder-bumps or direct bonding of copper pads with HBI, this approach may be considered the most promising candidate when attempting to integrate a diamond film into a 3D stack. On the other hand, the process is complex and likely time-consuming when the goal is to arrive at a manufacturable process.

Various examples of the present disclosure are based on the finding that conventional interconnection techniques in semiconductor die stacks face significant challenges in balancing electrical connectivity with thermal management. Traditional interconnection materials often suffer from limited thermal conductivity, which can lead to heat accumulation and performance degradation in multi-die assemblies. The proposed concept addresses this technical problem by utilizing diamond-based films, with laser-induced graphitic structures, that simultaneously provide both electrical connectivity and superior thermal dissipation capabilities.

This proposed concept makes use of a recent development of creating conductive paths in diamond wafers using laser pulses to modify the diamond structural properties in a very localized region, creating novel graphitic structures. The proposed concept is based on applying laser pulses to regions in the diamond films that are required to conduct electrical power or signals between components arranged adjacent to the diamond-based films. In particular, focused laser pulses may be used to locally heat the diamond material above its graphitization threshold (˜1700° C.). This converts the sp³-bonded carbon atoms in diamond into sp²-bonded graphitic carbon, which is electrically conductive. When the laser pulses are applied to specific locations on the diamond-based film, the absorbed laser energy breaks the sp³ bonds and rearranges carbon atoms into conductive graphitic or amorphous carbon phases. Multiple pulses or scanning can create pad-sized graphitic structures that match the contact pad patterns of the adjacent components, while the remainder of the diamond-based film stays non-conductive, thereby ensuring insulation between the conductive paths. By using this process, a diamond film can be deposited or grown on a wafer or die, and the laser pulse process can be used to create electrically conductive paths through the diamond film that allow the dies or wafers to electrically communicate with each other.

The proposed concept therefore provides a technique for creating electrically conductive pathways within thermally conductive diamond-based films for semiconductor die stacks. By selectively graphitizing localized regions of a diamond-based film using laser pulses, the proposed concept enables the formation of conductive structures that electrically connect adjacent semiconductor dies while maintaining the exceptional thermal conductivity of the surrounding diamond material. This improves both the electrical performance and thermal management of die stacks, enabling higher integration densities and enhanced reliability. The proposed concept results in die stacks with reduced thermal resistance and improved heat dissipation compared to conventional interconnection technologies, while simultaneously providing robust electrical connectivity between stacked dies. This concept can potentially remove several manufacturing steps in a process that seeks to optimize a thermal solution in the area of 3D die-stacking, which suffers from thermal limits as its primary restriction for more extensive use.

This proposed concept, especially when combined with other new proposed concepts being developed, has the potential to fundamentally reset what is possible in the arena of 3D die stacking and to create a low-SWaP (size, weight, and power) packaging solution, and even a compute solution that redefines compute power efficiency.

As outlined above, the proposed concept relates to the use of a laser pulse to create electrically conductive vias through a diamond thin film by modifying the diamond locally into a graphitic structure. Such diamond thin films may be used in a 3D stack-up of active electrical silicon-based components that communicate with one another. Various examples of the present disclosure relate to the use of potential options for improving the hybrid bond interconnect between the diamond thin film and the other die/wafer that includes both the dielectric (i.e., SiOx, SiNx, SiCN, etc.) and the electrically conductive connections (i.e., copper pads). Bonding with the copper pads can be improved using potential options such as selective deposition on these pads with titanium, tantalum, tungsten, or other materials, which then subsequently bond more readily to the diamond film and specifically the conductive graphitic vias created by the laser pulse process. This intermediary film ideally enables electrical conductivity while minimizing any resistive increase by an additionally created compound between the diamond and copper.

This proposed concept starts with an assumption of diamond-like thin films residing between multiple (e.g., 2, 4, 8, 16+) dies, such as chiplets comprising compute, memory, or network functionality, etc., that are stacked in a 3D fashion. These components need to exchange data and allow electrical connection to the rest of the system. Therefore, the diamond-like film enables electrically conductive pathways (called vias) from one side of a component through the film to the other side of the film, and a high number of pathways are required.

The present disclosure thus provides a diamond-based film for a die stack. FIG. 2 shows an example of such a diamond film 1 with laser-created electrically conductive graphitic vias 2 being bonded to a die 3 via a dielectric film 4. The diamond-based film 1 comprises a plurality of laser-induced graphitic structures 2 configured to provide electrical connectivity between a first semiconductor die and a second semiconductor die arranged adjacent to the diamond-based film in the die stack. These graphitic structures 2 act as vias that provide an electrical connection between contacts on either side of the diamond-based film. By incorporating laser-induced graphitic structures within the diamond-based film, the proposed concept achieves the dual functionality of electrical interconnection and thermal management, thereby improving overall die stack performance and reliability.

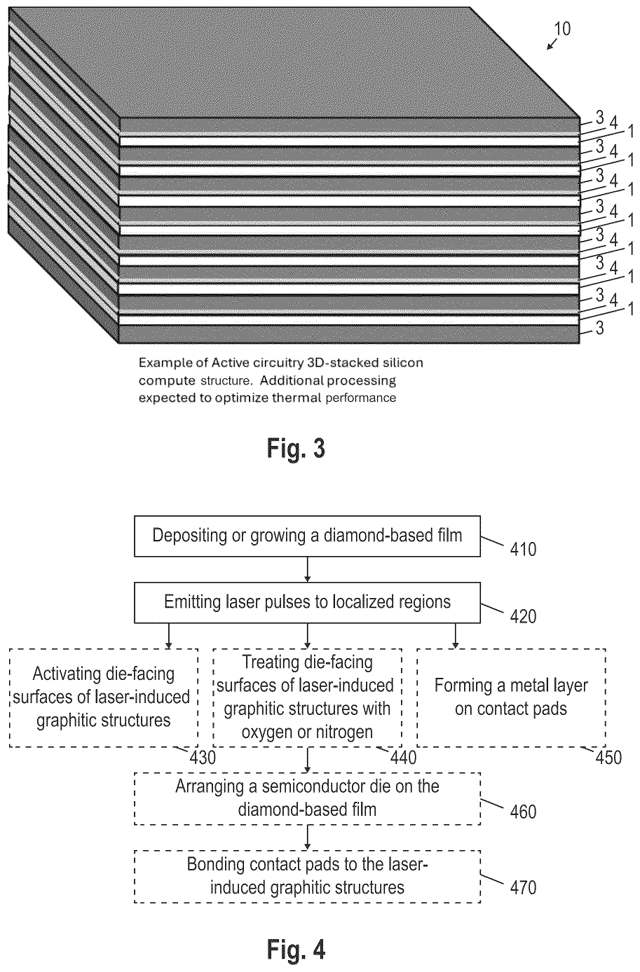

The diamond-based film is particularly useful in die stacks. Some aspects of the present disclosure thus relate to a die stack (e.g., die stack 10 of FIG. 3). The die stack comprises a first semiconductor die 3, a second semiconductor die 3 (the first and second semiconductor dies are dies that are arranged adjacent to each other in the stack, bar the diamond-based film that is arranged between them), and the diamond-based film 1. The diamond-based film 1 is arranged adjacent to the first and second semiconductor dies 3. The laser-induced graphitic structures are configured to provide electrical connectivity between contacts 5 of the first semiconductor die and corresponding contacts 5 of the second semiconductor die. In particular, the contacts of the first and second semiconductor dies may be arranged to provide an electrical conduit through the laser-induced graphitic structures of the diamond-based film. By utilizing the diamond-based film with laser-induced graphitic structures as an interconnection medium, the die stack achieves superior thermal dissipation while maintaining robust electrical connections between stacked dies. In particular, for optimal thermal and electrical coupling between the semiconductor dies, the diamond-based film may be interposed between the first and second semiconductor dies. This configuration improves heat transfer from both dies into the thermally conductive diamond material while providing direct electrical pathways through the graphitic structures.

The creation of electrically conductive pathways (vias) is achieved by firing laser pulses that locally transform small regions of diamond into graphitic (carbon-rich, conductive) structures. In other words, to achieve controlled formation of the conductive pathways with precise geometries and electrical properties, the graphitic structures may be formed by modifying the structural properties of the diamond-based film in a localized region (i.e., so they are opposite the respective contacts of the dies arranged adjacent in the die stack) using one or more laser pulses. The laser pulses may induce graphitization of the diamond-based film. This laser-based approach enables precise control over the location, size, and conductivity of the graphitic structures without requiring complex lithographic processes. The electrically conductive pathways may be created without etching a via in the diamond film, creating a barrier film in that newly etched via, filling the via with a conductive material (typically copper), or removing the excess conductive material from all surfaces outside the via.

In general, the graphitic structures 2 may be created after the diamond-based film 1 has been deposited or grown on one of the dies. For example, to facilitate manufacturing and ensure intimate contact between the diamond-based film and the semiconductor dies, the diamond-based film may be deposited or grown on a surface of the first or second semiconductor die. This direct deposition or growth approach eliminates the need for separate bonding processes and enhances both thermal and mechanical coupling. After the diamond-based film 1 has been formed on the die, the graphitic structures may be created using laser pulses. Once these conductive pathways are created in the exposed diamond layer on top of the chiplet, the diamond layer 1 may be bonded to the base layer of the subsequent chiplet, which typically contains exposed copper pads 5 and an insulating layer 4 such as SiOx (Silicon oxide, where x indicates a variable oxygen content), SiNx (Silicon nitride), or SiCN (Silicon Carbon nitride). Thus, at least one of the first semiconductor die or the second semiconductor die may comprise a dielectric layer 4 facing the diamond-based film. The contacts 5 of the respective semiconductor die may be exposed through the dielectric layer 4. For example, the contacts 5 of the first and second semiconductor dies may comprise copper. This arrangement ensures that electrical connectivity is established only through the designated contact points while maintaining proper isolation of other circuit elements.

To enable these connections (both dielectric and conductor), the diamond film may effectively bond to these surfaces. While diamond bonds well with these insulators 4, forming a robust and conductive link to copper is more challenging. To address this, the proposed concept suggests several approaches.

To address challenges with adhesion and electrical contact resistance between the graphitic structures and the semiconductor die contacts, a first approach is to add a very thin layer of metal such as titanium, tantalum, or tungsten onto the copper pad. In other words, a metal layer (e.g., a metal layer of at most 100 micron, or at most 50 micron, or at most 20 micron thickness) may be formed between at least a subset of the contacts of the first and second semiconductor dies and the laser-induced graphitic structures of the diamond-based film. This intermediate metal layer improves bonding strength and reduces interfacial resistance, thereby enhancing both mechanical stability and electrical performance. For example, the metal layer may comprise at least one metal of the group of titanium, tantalum, or tungsten. These refractory metals form strong bonds with carbon-based materials and are compatible with semiconductor processing, ensuring reliable interfacial connections. This “intermediate” layer can bond more easily to both copper and diamond, especially the graphitic parts created by laser pulses. The result is a strong and conductive connection with minimal resistance. FIG. 2 illustrates a selective deposition of adhesion-promotion thin-film 6 over the Cu (copper) pads 5 present in the dielectric film 4. The die 3 shown on top may be flipped over to HBI bond on the diamond-film 1 deposited on the die/wafer.

In scenarios requiring direct bonding without intermediate metal layers, in a second approach, the surface of the diamond or graphitic carbon may be treated or “activated” to bond directly with copper. In other words, die-facing surfaces of the laser-induced graphitic structures may be activated to bond to the contacts of the first and second semiconductor dies. Surface activation enhances the chemical reactivity of the graphitic surfaces, enabling direct bonding to the semiconductor contacts and simplifying the manufacturing process.

For enhanced bonding through chemical compound formation, a third approach may include modifying the diamond or carbon surfaces with nitrogen or oxygen, creating an ultra-thin compound layer to assist bonding. In other words, die-facing surfaces of the laser-induced graphitic structures may be treated with oxygen or nitrogen to form a compound layer for bonding to the contacts of the first and second semiconductor dies. This surface treatment creates reactive compound layers, such as oxides or nitrides, that facilitate strong chemical bonds with the semiconductor contacts.

The above approaches are applicable to the successful deposition and electrical connectivity of the diamond layer with the die (e.g., chiplet) on which it is deposited.

FIG. 3 shows an example of a resulting active circuitry 3D-stacked silicon compute structure 10 (i.e., a die stack). Additional processing may be performed to improve the thermal performance. As shown in the die stack 10 of FIG. 3, to improve thermal management throughout an entire multi-die assembly, a diamond-based film 1 may be arranged between each pair of adjacent semiconductor dies 3. This comprehensive integration of diamond-based films provides superior thermal dissipation across all die interfaces in the stack. Alternatively, as shown in FIG. 1, the die stack may comprise at least one pair of adjacent semiconductor dies without a diamond-based film arranged between the semiconductor dies. This selective integration approach allows a trade-off between cost and thermal management by incorporating diamond-based films only where thermal dissipation requirements are most critical.

More details and aspects of the diamond-based film 1 and the die stack 10 are mentioned in connection with the proposed concept or one or more examples described above or below (e.g., FIG. 4). The diamond-based film 1 and the die stack 10 may comprise one or more additional optional features corresponding to one or more aspects of the proposed concept or one or more examples described above or below.

FIG. 4 shows a flowchart of an example of a method for forming a diamond-based film for a die stack, such as the diamond-based film 1 and die stack 10 of FIGS. 1 to 3. The method comprises depositing 410 or growing the diamond-based film on a semiconductor die or wafer. The method comprises emitting 420 laser pulses to localized regions of the diamond-based film to create a plurality of laser-induced graphitic structures configured to provide electrical connectivity between semiconductor dies arranged adjacent to the diamond-based film in the die stack. By combining diamond film deposition with laser-induced graphitization, the method enables fabrication of interconnection structures with both excellent thermal conductivity and electrical connectivity.

The deposition or growth of the diamond-based film on a semiconductor die or wafer can be implemented using chemical vapor deposition (CVD) techniques, which are commonly used for producing high-quality diamond films in semiconductor manufacturing. The process typically employs microwave plasma-enhanced CVD (MPCVD) or hot filament CVD (HFCVD), where a gas mixture containing a carbon source (such as methane, CH₄) diluted in hydrogen is introduced into a reaction chamber. Prior to deposition, the semiconductor die or wafer surface may be seeded with nanodiamond particles through ultrasonic treatment in a diamond slurry or by spin-coating a nanodiamond suspension, which provides nucleation sites for diamond growth and improves film uniformity and adhesion. For integration with semiconductor processing, lower-temperature deposition methods such as plasma-enhanced CVD at temperatures below 400° C. may be employed to prevent thermal damage to the underlying device structure.

The laser-induced graphitization of localized regions within the diamond-based film can be implemented using pulsed laser systems, typically femtosecond or picosecond lasers operating at wavelengths that are absorbed by diamond, such as ultraviolet (UV) wavelengths below 225 nm or near-infrared wavelengths around 1030 nm for multi-photon absorption processes. The laser system may be integrated with a precision positioning stage and optical focusing system that enables accurate alignment of the laser focal point with the intended graphitic structure locations, which correspond to the copper pad positions on the adjacent semiconductor dies. The laser pulses may be focused through a high numerical aperture objective lens to achieve spot sizes in the micrometer range, and the focal depth may be controlled to create graphitic structures that extend through the entire thickness of the diamond film. For creating pad-sized graphitic structures that match the contact patterns of adjacent components, the laser beam may be scanned in a controlled pattern using galvanometer mirrors or by translating the substrate on a precision XY stage, with multiple overlapping pulses applied to build up the desired via geometry.

As outlined in connection with FIGS. 1 to 3, there are various approaches for ensuring proper adhesion between the (copper) contact pads of the dies and the graphitic structures. For example, the method may further comprise activating die-facing surfaces of the laser-induced graphitic structures to bond to contact pads of the adjacent semiconductor dies. This activation step increases surface reactivity and facilitates robust direct bonding. Surface activation of the graphitic structures for direct bonding to copper can be implemented using plasma-based treatments or ion beam bombardment techniques. This process may involve exposing the die-facing surfaces of the laser-induced graphitic structures to an argon or nitrogen plasma at low pressure (typically 10-100 mTorr) for a controlled duration of several seconds to minutes. This plasma treatment removes surface contaminants and dangling bonds while creating reactive surface sites with increased surface energy that promote adhesion to copper. Alternatively, a more aggressive activation can be achieved using fast atom beam (FAB) activation in an ultra-high vacuum environment, where argon atoms are accelerated toward the graphitic surface to create highly reactive dangling bonds. Following activation, the surfaces may be bonded within a limited time window (typically minutes to hours) before the activated state decays through atmospheric contamination. The bonding process itself may be performed by bringing the activated graphitic surfaces into contact with the copper pads under controlled pressure and temperature conditions, often in a vacuum or inert atmosphere. The activated carbon atoms on the graphitic surface may form direct covalent or metallic bonds with the copper atoms, creating an interface with low electrical resistance and strong mechanical adhesion without requiring an intermediate layer.

Alternatively, for improved bonding through chemical compound formation at the interface, the method may further comprise treating 440, die-facing surfaces of the laser-induced graphitic structures with oxygen or nitrogen to form a compound layer for bonding to the contacts of the adjacent semiconductor dies. This treatment creates chemically reactive surfaces that enhance bonding to the semiconductor contacts. The surface treatment approach using oxygen or nitrogen to form a compound layer can be implemented through controlled oxidation or nitridation processes applied to the graphitic structure surfaces. For oxygen treatment, the graphitic surfaces may be exposed to an oxygen plasma or ozone environment at elevated temperatures (200-400° C.), which introduces oxygen functional groups such as hydroxyl, carbonyl, and carboxyl groups onto the carbon surface. These oxygen-containing groups create a thin oxide-like layer (typically 1-5 nanometers) that exhibits enhanced chemical reactivity with copper, forming copper-oxygen-carbon bonds at the interface during subsequent bonding. For nitrogen treatment, the graphitic surfaces may be exposed to a nitrogen or ammonia plasma, which incorporates nitrogen atoms into the carbon lattice and creates surface amine and imine groups. This nitridation process may also be performed using ion implantation with nitrogen ions at low energies to confine the modification to the near-surface region. The resulting nitrogen-doped carbon surface may form strong bonds with copper through the formation of copper-nitrogen coordination complexes. Both treatments can be precisely controlled in terms of depth and concentration using process parameters such as plasma power, exposure time, temperature, and gas pressure. The compound layer acts as a chemical bridge between the graphitic carbon and the copper pad, providing both strong mechanical adhesion through covalent bonding and low electrical contact resistance through the formation of conductive interfacial compounds.

As a further alternative, the method may further comprise forming 450 a metal layer on contact pads of at least one of the adjacent semiconductor dies. This metal layer formation provides an intermediate bonding layer that improves both mechanical and electrical connections between the graphitic structures and the semiconductor contacts. The intermediate metal layer approach can be implemented by depositing a thin film of titanium, tantalum, or tungsten onto the copper pads prior to bonding with the diamond-based film. This deposition may typically be performed using physical vapor deposition (PVD) techniques such as sputtering or electron beam evaporation, which allow precise control over film thickness in the range of 10-100 nanometers. After deposition, a low-temperature annealing step may be performed to promote interdiffusion and compound formation at the metal-copper interface, creating a metallurgically stable bond before the diamond film with graphitic vias is brought into contact for hybrid bonding.

The proposed method may be used in the manufacturing of a die stack. Therefore, the method may further comprise arranging 460 a (second) semiconductor die on the diamond-based film, i.e., on the opposite side of the diamond-based film.

To improve mechanical and electrical connections between the die stack components, the method may comprise 470 bonding (e.g., HBI bonding) contact pads of a semiconductor die or wafer arranged adjacent to the diamond-based film and to the laser-induced graphitic structures. This bonding operation creates or improves the electrical pathways and mechanical attachment between the semiconductor dies through the diamond-based film.

After the chiplet with the diamond film is bonded to the other chip—whether in die-to-die, die-to-wafer, or wafer-to-wafer arrangements—the rest of the manufacturing process may use similar industry operations for building up 3D stacks. In particular, the process may be repeated for additional dies of the die stack. While there will be further operations for leveraging the diamond's high thermal conductivity in these stacks, those details are outside the scope of this proposed concept.

More details and aspects of the diamond-based film 1, the die stack 10, and the method are mentioned in connection with the proposed concept or one or more examples described above or below (e.g., FIGS. 1 to 3). The diamond-based film 1, the die stack 10, and the method may comprise one or more additional optional features corresponding to one or more aspects of the proposed concept or one or more examples described above or below.

The proposed concept relates to a diamond-based film between die stacks. The diamond-based film provides electrical connectivity between dies without metal vias or other conductive materials filling patterned diamond film holes. Copper pads may be arranged on the die layer below the diamond layer and on the other side of the diamond film. The proposed concept uses a change in crystalline structure of the diamond film to conclusively provide electrical connectivity.

In the following, some examples of the proposed concept are presented:

An example (e.g., example 1) relates to a diamond-based film (1) for a die stack (10), comprising a plurality of laser-induced graphitic structures (2) configured to provide electrical connectivity between a first semiconductor die (3) and a second semiconductor die (3) arranged adjacent to the diamond-based film in the die stack.

Another example (e.g., example 2) relates to a previous example (e.g., example 1) or to any other example, further comprising that the graphitic structures are formed by modifying the structural properties of the diamond-based film in a localized region using one or more laser pulses, wherein the laser pulses induce graphitization of the diamond-based film.

An example (e.g., example 3) relates to a die stack (10), comprising a first semiconductor die (3), a second semiconductor die (3), and the diamond-based film (1) according to one of the examples 1 or 2, arranged adjacent to the first and second semiconductor dies, wherein the laser-induced graphitic structures (2) are configured to provide electrical connectivity between contacts (5) of the first semiconductor die and corresponding contacts (5) of the second semiconductor die.

Another example (e.g., example 4) relates to a previous example (e.g., example 3) or to any other example, further comprising that the diamond-based film is interposed between the first and second semiconductor dies.

Another example (e.g., example 5) relates to a previous example (e.g., one of the examples 3 or 4) or to any other example, further comprising that the diamond-based film is deposited or grown on a surface of the first or second semiconductor die.

Another example (e.g., example 6) relates to a previous example (e.g., one of the examples 3 to 5) or to any other example, further comprising that at least one of the first semiconductor die or the second semiconductor die comprises a dielectric layer (4) facing the diamond-based film, wherein the contacts (5) of the respective semiconductor die are exposed through the dielectric layer.

Another example (e.g., example 7) relates to a previous example (e.g., one of the examples 3 to 6) or to any other example, further comprising that the contacts of the first and second semiconductor dies comprise copper.

Another example (e.g., example 8) relates to a previous example (e.g., one of the examples 3 to 7) or to any other example, further comprising that the contacts of the first and second semiconductor dies are arranged to provide an electrical conduit through the laser-induced graphitic structures of the diamond-based film.

Another example (e.g., example 9) relates to a previous example (e.g., one of the examples 3 to 8) or to any other example, further comprising that a metal layer (6) is formed between at least a subset of the contacts (5) of the first and second semiconductor dies and the laser-induced graphitic structures of the diamond-based film.

Another example (e.g., example 10) relates to a previous example (e.g., example 9) or to any other example, further comprising that the metal layer comprises at least one metal of the group of titanium, tantalum, or tungsten.

Another example (e.g., example 11) relates to a previous example (e.g., one of the examples 3 to 8) or to any other example, further comprising that die-facing surfaces of the laser-induced graphitic structures are activated to bond to the contacts of the first and second semiconductor dies.

Another example (e.g., example 12) relates to a previous example (e.g., one of the examples 3 to 8) or to any other example, further comprising that die-facing surfaces of the laser-induced graphitic structures are treated with oxygen or nitrogen to form a compound layer for bonding to the contacts of the first and second semiconductor dies.

Another example (e.g., example 13) relates to a previous example (e.g., one of the examples 3 to 12) or to any other example, further comprising that a diamond-based film is arranged between each pair of adjacent semiconductor dies.

Another example (e.g., example 14) relates to a previous example (e.g., one of the examples 3 to 12) or to any other example, further comprising that the die stack comprises at least one pair of adjacent semiconductor dies without a diamond-based film arranged between the semiconductor dies.

An example (e.g., example 15) relates to a method for forming a diamond-based film for a die stack, comprising depositing or growing (410) the diamond-based film on a semiconductor die or wafer, and emitting (420) laser pulses to localized regions of the diamond-based film to create a plurality of laser-induced graphitic structures configured to provide electrical connectivity between semiconductor dies arranged adjacent to the diamond-based film in the die stack.

Another example (e.g., example 16) relates to a previous example (e.g., example 15) or to any other example, further comprising that the method further comprises activating (430) die-facing surfaces of the laser-induced graphitic structures to bond to contact pads of the adjacent semiconductor dies.

Another example (e.g., example 17) relates to a previous example (e.g., example 15) or to any other example, further comprising that the method further comprises treating (440) die-facing surfaces of the laser-induced graphitic structures with oxygen or nitrogen to form a compound layer for bonding to the contacts of the adjacent semiconductor dies.

Another example (e.g., example 18) relates to a previous example (e.g., example 15) or to any other example, further comprising that the method further comprises forming (450) a metal layer on contact pads of at least one of the adjacent semiconductor dies.

Another example (e.g., example 19) relates to a previous example (e.g., one of the examples 15 to 18) or to any other example, further comprising that the method further comprises arranging (460) a semiconductor die on the diamond-based film.

Another example (e.g., example 20) relates to a previous example (e.g., one of the examples 15 to 19) or to any other example, further comprising that the method comprises bonding (470) contact pads of a semiconductor die or wafer arranged adjacent to the diamond-based film to the laser-induced graphitic structures.

The aspects and features described in relation to a particular one of the previous examples may also be combined with one or more of the further examples to replace an identical or similar feature of that further example or to additionally introduce the features into the further example.

It is further understood that the disclosure of several steps, processes, operations, or functions disclosed in the description or claims shall not be construed to imply that these operations are necessarily dependent on the order described, unless explicitly stated in the individual case or necessary for technical reasons. Therefore, the preceding description does not limit the execution of several steps or functions to a certain order. Furthermore, in further examples, a single step, function, process, or operation may include and/or be broken up into several sub-steps,-functions,-processes, or-operations.

If some aspects have been described in relation to a device or system, these aspects should also be understood as a description of the corresponding method. For example, a block, device, or functional aspect of the device or system may correspond to a feature, such as a method step, of the corresponding method. Accordingly, aspects described in relation to a method shall also be understood as a description of a corresponding block, a corresponding element, a property, or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of one claim should also be included for any other independent claim, even if that claim is not directly defined as dependent on that other independent claim.

What is claimed is:

1. A diamond-based film for a die stack, comprising a plurality of laser-induced graphitic structures configured to provide electrical connectivity between a first semiconductor die and a second semiconductor die arranged adjacent to the diamond-based film in the die stack.

2. The diamond-based film according to claim 1, wherein the graphitic structures are formed by modifying the structural properties of the diamond-based film in a localized region using one or more laser pulses, wherein the laser pulses induce graphitization of the diamond-based film.

3. A die stack, comprising:
a first semiconductor die;
a second semiconductor die; and
the diamond-based film according to claim 1, arranged adjacent to the first and second semiconductor dies, wherein the laser-induced graphitic structures are configured to provide electrical connectivity between contacts of the first semiconductor die and corresponding contacts of the second semiconductor die.

4. The die stack according to claim 3, wherein the diamond-based film is interposed between the first and second semiconductor dies.

5. The die stack according to claim 3, wherein the diamond-based film is deposited or grown on a surface of the first or second semiconductor die.

6. The die stack according to claim 3, wherein at least one of the first semiconductor die or the second semiconductor die comprises a dielectric layer facing the diamond-based film, wherein the contacts of the respective semiconductor die are exposed through the dielectric layer.

7. The die stack according to claim 3, wherein the contacts of the first and second semiconductor dies comprise copper.

8. The die stack according to claim 3, wherein the contacts of the first and second semiconductor dies are arranged to provide an electrical conduit through the laser-induced graphitic structures of the diamond-based film.

9. The die stack according to claim 3, wherein a metal layer is formed between at least a subset of the contacts of the first and second semiconductor dies and the laser-induced graphitic structures of the diamond-based film.

10. The die stack according to claim 9, wherein the metal layer comprises at least one metal of the group of titanium, tantalum, or tungsten.

11. The die stack according to claim 3, wherein die-facing surfaces of the laser-induced graphitic structures are activated to bond to the contacts of the first and second semiconductor dies.

12. The die stack according to claim 3, wherein die-facing surfaces of the laser-induced graphitic structures are treated with oxygen or nitrogen to form a compound layer for bonding to the contacts of the first and second semiconductor dies.

13. The die stack according to claim 3, wherein a diamond-based film is arranged between each pair of adjacent semiconductor dies.

14. The die stack according to claim 3, wherein the die stack comprises at least one pair of adjacent semiconductor dies without a diamond-based film arranged between the semiconductor dies.

15. A method for forming a diamond-based film for a die stack, comprising:
depositing or growing the diamond-based film on a semiconductor die or wafer; and
emitting laser pulses to localized regions of the diamond-based film to create a plurality of laser-induced graphitic structures configured to provide electrical connectivity between semiconductor dies arranged adjacent to the diamond-based film in the die stack.

16. The method according to claim 15, wherein the method further comprises activating die-facing surfaces of the laser-induced graphitic structures to bond to contact pads of the adjacent semiconductor dies.

17. The method according to claim 15, wherein the method further comprises treating die-facing surfaces of the laser-induced graphitic structures with oxygen or nitrogen to form a compound layer for bonding to the contacts of the adjacent semiconductor dies.

18. The method according to claim 15, wherein the method further comprises forming a metal layer on contact pads of at least one of the adjacent semiconductor dies.

19. The method according to claim 15, wherein the method further comprises arranging a semiconductor die on the diamond-based film.

20. The method according to claim 15, wherein the method comprises bonding contact pads of a semiconductor die or wafer arranged adjacent to the diamond-based film to the laser-induced graphitic structures.
